(19) United States
(12) Patent Application Publication
(10) Pub. No.: US 2026/0293220 A1
(43) Pub. Date: Sep. 24, 2026

(54) METHODS FOR FABRICATING VERTICAL SEMICONDUCTOR DEVICE WITH ROBUST GATE REGION AND EDGE TERMINATION REGION AND STRUCTURES

(71) Applicant: SEMICONDUCTOR COMPONENTS INDUSTRIES, LLC, Scottsdale, AZ (US)

(72) Inventors: Clifford Ian DROWLEY, Los Altos, CA (US); Subhash Srinivas PIDAPARTHI, San Jose, CA (US); Michael David CRAVEN, San Jose, CA (US)

(73) Assignee: SEMICONDUCTOR COMPONENTS INDUSTRIES, LLC, Scottsdale, AZ (US)

(21) Appl. No.: 19/548,840

(22) Filed: Feb. 24, 2026

Related U.S. Application Data
(60) Provisional application No. 63/774,646, filed on Mar. 19, 2025.

(51) Int. Cl. H10D 30/83; H10D 30/01; H10D 62/10; H10D 62/60; H10D 62/85

(52) U.S. Cl. CPC H10D 30/831; H10D 30/0515; H10D 62/124; H10D 62/60; H10D 62/8503; H10D 62/105

(57) ABSTRACT

A vertical, fin-based FET device includes a semiconductor substrate and drift region over the semiconductor substrate. A first gate region portion is on the drift region. Trenches extend through the first gate region portion to the drift region. Fins are within the trenches, extend above the first gate region portion. A second gate region portion is on the first gate region portion and surrounds the fins. The first gate region portion and the drift region form an as-grown interface, the second gate region portion and the first gate region portion form a regrown interface, and the fins comprise base portions within the trenches and upper portions coupled to the base portions and extending above the trenches.

### CROSS-REFERENCES TO RELATED APPLICATIONS

This application claims priority from U.S. Provisional Patent Application No. 63/774,646 filed on Mar. 19, 2025, which is hereby incorporated by reference in its entirety.

### BACKGROUND

Vertical power transistors, in which the current flows from the top surface of the transistor to the back or bottom surface of the transistor substrate, are commonly used for controlling high currents and high voltages, since they can be formed with a reduced area compared to devices in which current flow through the transistor (e.g., a field effect transistor (FET)) is lateral.

III-nitride materials, and in particular, gallium nitride (GaN), allow vertical FET-based power transistors to be fabricated with high breakdown voltages (e.g., in excess of 1200 V) while offering significant reductions in the specific on-resistance (i.e., the on-resistance of the device multiplied by the device area) compared to silicon or silicon carbide materials.

Despite the progress made in the area of vertical power transistors, there is a need in the art for improved methods and systems related to vertical power transistors.

### BRIEF DESCRIPTION OF THE DRAWINGS

FIG. 1 is a partial cross-sectional view illustrating a vertical, fin-based junction FET (JFET) device according to an embodiment of the present description.

FIGS. 2, 3, 4, 5, and 6 are partial cross-sectional views illustrating an example method of fabricating a vertical, fin-based FET device according to an embodiment of the present description.

FIG. 7 is a Weibull Cumulative Distribution Function (Weibull CDF) chart that shows the probability of time to failure for an as-grown PN junction device according to the present description compared to a regrown PN junction device.

FIG. 8 is a graph illustrating the shift in the location of high electric field from a regrown interface for a vertical, fin-based JFET device according to the present description compared to a prior vertical, fin-based JFET device.

FIG. 9 is a graph illustrating drain current/voltage (I/V) characteristics for a vertical, fin-based JFET device according to the present description compared to a prior vertical, fin-based JFET device.

FIG. 10 is a partial cross-sectional view illustrating a vertical, fin-based JFET device that includes an active fin and an inactive fin according to an embodiment of the present description.

FIGS. 11, 12, and 13 are partial cross-sectional views illustrating an example method of fabricating a vertical, fin-based JFET device with an active fin and an inactive fin according to an embodiment of the present description.

FIG. 14 is a cross-sectional view illustrating a prior vertical, fin-based JFET device.

The following discussion provides various examples of semiconductor devices and methods of manufacturing semiconductor devices. Such examples are non-limiting, and the scope of the appended claims should not be limited to the particular examples disclosed. In the following discussion, the terms “embodiment”, “example” and “e.g.” are non-limiting.

For simplicity and clarity of the illustration, elements in the figures are not necessarily drawn to scale, and the same reference numbers in different figures denote the same elements. Additionally, descriptions and details of well-known steps and elements are omitted for simplicity of the description.

For clarity of the drawings, certain regions of device structures, such as doped regions or dielectric regions, trenches, or contacts may be illustrated as having generally straight-line edges and precise angular corners. However, those skilled in the art understand that, due to the diffusion and activation of dopants or formation of layers, the edges of such regions generally may not be straight lines and that the corners may not be precise angles.

Although the semiconductor devices are explained herein as certain N-type conductivity regions and certain P-type conductivity regions, a person of ordinary skill in the art understands that the conductivity types can be reversed and are also possible in accordance with the present description, considering any necessary polarity reversal of voltages, inversion of transistor type and/or current direction, etc.

In addition, the terminology used herein is for the purpose of describing particular examples only and is not intended to be limiting of the disclosure. As used herein, the singular forms are intended to include the plural forms as well, unless the context clearly indicates otherwise.

As used herein, “current-carrying electrode” means an element of a device that carries current through the device, such as a source or a drain of an MOS transistor, an emitter or a collector of a bipolar transistor, or a cathode or anode of a diode, and a “control electrode” means an element of the device that controls current through the device, such as a gate of a MOS transistor or a base of a bipolar transistor.

The term “major surface” when used in conjunction with a semiconductor region, wafer, or substrate means the surface of the semiconductor region, wafer, or substrate that forms an interface with another material, such as a dielectric, an insulator, a conductor, or a polycrystalline semiconductor. A major surface can have a topography that changes in the x, y and z directions.

In addition, structures of the present description can embody either a cellular-base design (in which the body regions are a plurality of distinct and separate cellular or stripe regions) or a single-base design (in which the body region is a single region formed in an elongated pattern, typically in a serpentine pattern or a central portion with connected appendages). However, one embodiment of the present description will be described as a cellular base design throughout the description for ease of understanding. It is understood that the present description encompasses both a cellular-base design and a single-base design.

The terms “comprises”, “comprising”, “includes”, “including”, “has”, “have” and/or “having” when used in this description, are open ended terms that specify the presence of stated features, numbers, steps, operations, elements, and/or components, but do not preclude the presence or addition of one or more other features, numbers, steps, operations, elements, components, and/or groups thereof.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

Although the terms “first”, “second”, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

It will be appreciated by one skilled in the art that words, “during”, “while”, and “when” as used herein related to circuit operation are not exact terms that mean an action takes place instantly upon an initiating action but that there may be some small but reasonable delay, such as propagation delay, between the reaction that is initiated by the initial action. Additionally, the term “while” means a certain action occurs at least within some portion of a duration of the initiating action.

The use of word “about”, “approximately”, or “substantially” means a value of an element is expected to be close to a state value or position. However, as is well known in the art there are always minor variances preventing values or positions from being exactly stated. Unless specified otherwise, as used herein, the word “over” or “on” includes orientations, placements, or relations where the specified elements can be in direct or indirect physical contact.

Unless specified otherwise, as used herein, the word “overlapping” includes orientations, placements, or relations where the specified elements can at least partly or wholly coincide or align in the same or different planes.

It is understood that terms and phrases used in this document, and variations thereof, unless otherwise stated, should be construed as open ended as opposed to limiting. As examples of the foregoing: the term “including” should be read as meaning “including, without limitation” or the like; ; and adjectives such as “conventional,” “traditional,” “normal,” “standard,” “known”, and terms of similar meaning, should not be construed as limiting the item described to a given time period, or to an item available as of a given time. But instead, these terms should be read to encompass conventional, traditional, normal, or standard technologies that may be available, known now, or at any time in the future. Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to”, or other like phrases in some instances shall not be read to mean that the narrower case is intended or required in instances where such broadening phrases may be absent.

It is further understood that the examples illustrated and described hereinafter suitably may have examples and/or may be practiced in the absence of any element that is not specifically disclosed herein.

### DETAILED DESCRIPTION

Power semiconductor devices, including transistors and diodes, are widely used today in such applications as industrial power supplies, motor drives, consumer electronics, and other systems. A common application of power semiconductor transistors is their use as switches in switch-mode power supplies or motor drives. In such applications, the ability of the device to operate at high voltages (650 V or 1200 V, for example) and to withstand momentary over-voltage conditions (line surges or lightning strikes on power lines, for example) are important.

In addition, to reduce the resistance of the switch and reduce parasitic effects (e.g., capacitances) that limit switch speed, an increased conductance per unit area is desirable. Switch transistors in which the current flow is primarily vertical offer reduced resistance per unit area. This benefit can be further improved by arranging the control channel of the transistor to lie in the vertical direction, for example, a trench-channel transistor. The resistance of the transistor has several components, including the resistance of the transistor channel (i.e., the region where current is directly controlled by the input gate voltage), the resistance of the drift region (i.e., the region designed to hold the breakdown voltage of the transistor), and the resistance of the starting substrate, contacts, metals, packaging structures, and other elements.

Transistors with vertical current flow are typically designed with the drain contact at the bottom surface of the chip, and the gate and source contacts at the top surface of the chip.

In order to maximize the switch conductivity (i.e., minimize the switch resistance) and provide a uniform transient response for the device, the transistor may be fabricated using an array of many small, vertical-channel switch devices surrounded by control gates, which can be referred to as an array of “gate-all-around” transistors. The finished device has all sources connected to a single electrode, a common gate electrode, and a drain electrode.

The present description generally relates to the field of electronics, and more specifically to semiconductor manufacturing technology. In a particular example, structures and methods of forming arrays of vertical, fin-based FETs (FinFETs), i.e., FinFET arrays, with improved vertical device performance and reliability, are provided. Vertical, fin-based FETs include a gate-drain interface that may be subject to a full voltage applied to the device. This gate-drain interface typically is more robust than other design approaches. However, any impurities, contaminants, or defects present at the gate-drain interface can degrade the performance and operating lifetime of the vertical, fin-based FET device.

The methods and structures described herein improve the robustness of the gate-drain interface in vertical fin-based FETs by using fabrication techniques that can include multiple epitaxially grown regions provided in a single epitaxial growth process. In an example, a first portion of the gate region, specifically the part that contacts the drain, is formed during the same epitaxial growth process used to create the drift region portion of the drain region, rather than through a separate, second epitaxial growth step. This fabrication method enhances the structural and electrical integrity of the gate-drain interface by forming the drain-contacting portion of the gate region during the same epitaxial growth step used to form the drift region portion of drain region. Among other things, consolidating these regions into a single epitaxial process reduces heterointerfaces associated with regrown junctions and reduces defect densities, such as threading dislocations, point defects, and impurity incorporation, that commonly arise during separate regrowth steps. As a result, the gate-drain junction benefits from a more uniform doping profile, improved crystallographic alignment, and reduced trap assisted leakage pathways, enabling higher breakdown voltages. The methods and structure described herein can also facilitate increased drain current and a more robust edge termination region.

The methods and structures described herein provide improved device performance and reliability by replacing regrown junctions with as-grown junctions formed within epitaxially-grown semiconductor layers and by increasing the distance between high electric field regions and the epitaxial interface areas that are regrown interfaces. The method and structures described herein provide independent design capability for gate-drain and gate-source interfaces and provide enhanced edge termination design capabilities through improved processing and the ability to control the doping of the gate region and to form adjacent regions of opposite conductivity type epitaxially. The methods and structures described herein provide improved FET saturation current and reduced on-resistance by eliminating a parasitic high threshold voltage channel at the bottom of the vertical fins.

The methods and structures described herein can be used to provide non-active or inactive fins in certain regions of the device. In some examples, the inactive fins improve lithography process, etch process, and epitaxial growth process uniformity across an entire device (including the edge termination area) thereby improving device performance and lifetime. The methods and structures described herein apply to high voltage fin-based or trench-based vertical channel devices, including, for example, vertical GaN and SiC power devices. They also support high-efficiency, high-frequency power systems up to 10 MHz (e.g., for data center and EVB drivetrain applications, among other examples). While the examples described herein related vertical, fin-based JFET devices, it is understood that the method and structures described can be used for other semiconductor devices, including, but not limited to, metal-oxide-semiconductor FET (MOSFET) and super-junction MOSFET devices.

In an example, a vertical, fin-based FET device includes a semiconductor substrate characterized by a first conductivity type. A drift region is over the semiconductor substrate and is characterized by the first conductivity type and a first dopant concentration. A first gate region portion is on the drift region and is characterized by a second conductivity type opposite to the first conductivity type and a second dopant concentration. Trenches extend through the first gate region portion to the drift region. Fins are within the trenches, extend above the first gate region portion, are characterized by the first conductivity type and a third dopant concentration. A second gate region portion is on the first gate region portion, surrounds the fins, and is characterized by the second conductivity type and a fourth dopant concentration. In the present example, the first gate region portion and the drift region form an as-grown interface, the second gate region portion and the first gate region portion form a regrown interface, and the fins comprise base portions within the trenches and upper portions coupled to the base portions and extending above the trenches.

In an example, a vertical, fin-based FET device includes a semiconductor substrate characterized by a first conductivity type and a drift region over the semiconductor substrate and characterized by the first conductivity type. A first gate region portion is on the drift region and is characterized by a second conductivity type opposite to the first conductivity type. A second gate region portion is on the first gate region portion and is characterized by the second conductivity type. Fins characterized by the first conductivity type are coupled to the drift region and extend through the first gate region portion and the second gate region portion. In the present example, the first gate region portion and the drift region form an as-grown PN junction, the second gate region portion and the first gate region portion form a regrown interface, and the fins comprise base portions adjacent to the drift region and upper portions coupled to the base portions.

In an example, a method for fabricating a vertical, fin-based FET device includes providing a semiconductor substrate characterized by a first conductivity type. The method includes in a first epitaxial growth process, forming a drift region over the semiconductor substrate and characterized by the first conductivity type and a first dopant concentration, and forming a first gate region portion on the drift region and characterized by a second conductivity type opposite to the first conductivity type and a second dopant concentration. The method includes forming trenches extending through the first gate region portion to the drift region. The method includes in a second epitaxial growth process, forming a fin channel region within the trenches, and over the first gate region portion, the fin channel region is characterized by the first conductivity type and a third dopant concentration. The method includes forming a recess region in the fin channel region to form fins. The method includes a third epitaxial growth process, forming a second gate region portion on the first gate region portion, surrounding the fins, and characterized by the second conductivity type and a fourth dopant concentration. In the present example, the first epitaxial growth process is an in-situ process that provides the first gate region portion and the drift region as an as-grown interface, the second gate region portion and the first gate region portion form a regrown interface, the fins comprise base portions within the trenches and upper portions coupled to the base portions and extending above the trenches.

Other examples are included in the present disclosure. Such examples may be found in the figures, in the claims, or in the description of the present disclosure.

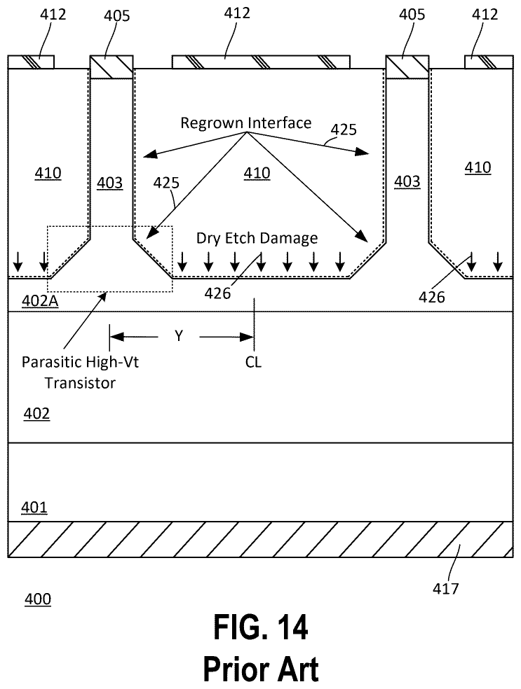

FIG. 14 is a partial cross-sectional view of a prior vertical, fin-based field effect transistor (FET) device 400. FET device 400 includes an N-type conductivity semiconductor substrate 401, an N-type conductivity drift region 402, an N-type conductivity graded doped layer 402A, and N-type conductivity fins 403 protruding vertically upward from graded doped layer 402A. FET device 400 further includes a regrown P-type conductivity gate region 410 surrounding fins 403 and having a bottom portion in direct contact with graded doped layer 402A. A source metal layer 405 contacts each of the fins 403, a gate metal layer 412 contacts gate region 410, and a drain metal layer 417 contacts the drain region at the bottom surface of semiconductor substrate 401.

In the past, to form fins 403, an epitaxial channel layer was disposed on graded doped layer 402A, a photolithographic process was used to provide a pattern for fins 403, and the exposed portions of the epitaxial channel layer were then removed to form a recess region that extended to graded doped layer 402A. Gate region 410 was then provided within the recess region using a separate epitaxial regrowth process, which provided a regrown interface as referenced by arrows 425.

This approach resulted in several issues. For example, after a first epitaxial growth process that provides the epitaxial channel layer, the etching step (e.g., dry etching) used to form the recess and to form fins 403 also damages graded doped layer 402A of drift region 402 at the base of the formed recess as referenced by arrows 426. Also, etch depth control combined with the presence of graded doped layer 402A can result in the formation of a parasitic high threshold voltage (Vt) at the lower portions of fins 403 adjoining graded doped layer 402A. This parasitic device can limit saturation drain current (i.e., restriction of current flow) and increase on-resistance in FET device 400. In addition, gate region 410 formed using a separate, second epitaxial growth (i.e., regrowth epitaxial growth) process results in a gate-drain interface that is etched damaged and susceptible to impurities incorporated during epitaxial growth initiation. Such damage and impurities can result in a reduction of high temperature reverse bias (HTRB) reliability. The present description addresses these issues as well as others.

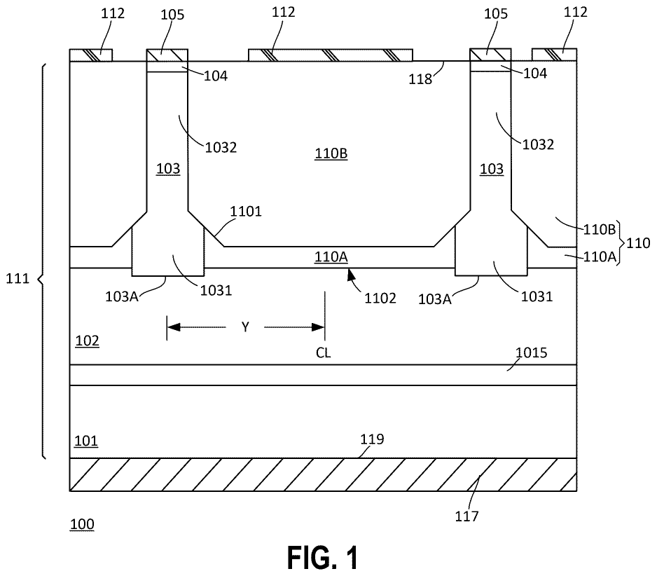

FIG. 1 illustrates a partial cross-sectional view of a vertical, fin-based junction field effect transistor (JFET) device 100 according to an embodiment of the present disclosure. The terms “FET,” “FinFET,” and “vertical, fin-based FET” are interchangeable as used herein. In the present example, vertical, fin-based JFET device 100 may include a semiconductor substrate 101, a buffer layer 1015, a drift region 102, which in some examples, can include a uniformly doped region on semiconductor substrate 101, and a plurality of fins 103 protruding upward from drift region 102. In some examples, each of the fins 103 may include a heavily doped contact regions 104 disposed in an upper portion of each fin and a contact 105, e.g., a refractory metal, refractory metal compound or refractory metal alloy layer (e.g., a TiN layer) disposed on each doped contact region 104. Contacts 105 can comprise or be referred to as a source contact. Doped contact regions 104 or contacts 105 are examples of a current-carrying electrode (e.g., a first current-carrying electrode).

In the present example, semiconductor substrate 101, buffer layer 1015, drift region 102 and fins 103 comprise a first conductivity type (e.g., N-type conductivity). In some examples, drift region 102 comprises a uniformly doped region as opposed to a graded doped region and comprises a similar dopant concentration to fins 103. More particularly, in the present example, vertical, fin-based JFET device 100 is devoid of an N-type conductivity graded doped layer, such as graded doped layer 402A described previously.

In the present example, semiconductor substrate 101, buffer layer 1015, drift region 102, or fins 103 can comprise a III-nitride semiconductor material, such as GaN, with an N-type conductivity. By way of example, the N-type conductivity can be provided using Si, Ge, or other dopant elements as known to one of ordinary skill in the art. It is understood that semiconductor substrate 101, buffer layer 1015, drift region 102, or fins 103 can comprise other semiconductor materials including, but not limited to, silicon, silicon carbide, silicon germanium, III-V materials, or similar materials as known to one of ordinary skill in the art.

In accordance with the present description, vertical, fin-based JFET device 100 includes multiple-part gate region 110, which comprises more than one gate region portion or gate region layer. That is, gate region 110 comprises a plurality of gate region portions in a vertically stacked configuration. In the present example, gate region 110 can comprise a III-nitride semiconductor material, such as GaN, with a second conductivity type (i.e., P-type conductivity) that is opposite the first conductivity type (i.e., N-type conductivity type). By way of example, the P-type conductivity can be provided using Mg, or other dopant elements as known to one of ordinary skill in the art. It is understood that gate region 110 can comprise other semiconductor materials including, but not limited to, silicon, silicon carbide, silicon germanium, III-V materials, or similar materials as known to one of ordinary skill in the art.

In the present example, gate region 110 comprises gate region portion 110A on drift region 102 and a gate region portion 110B on gate region portion 110A. In accordance with the present description, gate region portion 110A and gate region portion 110B are formed or provided using separate and distinct epitaxial growth processes. More particularly, gate region portion 110A is provided using the same epitaxial growth process that is used to form or provide drift region 102. In the present example, gate region portion 110A directly contacts drift region 102 to form an as-grown interface 1102.

In accordance with the present description, gate region portion 110A is formed in-situ after drift region 102 is formed in the same epitaxial reactor without removing semiconductor substrate 101 from the epitaxial reactor. This can include the same reactor chamber or a separate reactor chamber within a cluster epitaxial reactor having multiple chambers connected under vacuum. By forming gate region portion 110A in the same epitaxial growth sequence as drift region 102, the interface (i.e., as-grown interface 1102) between these regions is significantly improved. Because semiconductor substrate 101 is not removed from the epitaxial reactor during this process, the interface is protected from surface contamination, native oxide formation, moisture exposure, and other defects that typically arise when a semiconductor substrate is exposed to ambient conditions. In the present example, gate region portion 110B is formed at a later epitaxial growth process as will be described in more detail later. Gate region portion 110A can be an example of a first gate region portion and gate region portion 110B can be an example of a second gate region portion.

In some examples, gate region portion 110A can have the same or a different dopant concentration than gate region portion 110B. In some examples, gate region portion 110A has a lower dopant concentration than gate region portion 110B. More particularly, the PN junction formed between drift region 102 and gate region portion 110A can be tailored to modify a peak electric field at the PN junction during the operation of vertical, fin-based JFET device 100 to improve lifetime performance and/or an increase in breakdown voltage.

In vertical, fin-based JFET device 100, first ends 103A of fins 103 extend downward through gate region portion 110A and are coupled to drift region 102. In the present example, first ends 103A directly contact drift region 102, which is provided without a graded dopant layer. In some examples, first ends 103A can lie within a first plane and as-grown interface 1102 between drift region 102 and gate region portion 110B on a second plane that is different than the first plane. In some examples, the first plane can be recessed or below the second plane.

In some examples, the thickness of gate region portion 110A can be non-uniform. For example, the thickness of gate region portion 110A can increase proximately to fins 103 providing gate region portion 110A with a tapered upper surface 1101 at a location that is adjacent to fins 103. In some examples, gate region portion 110A comprises a first thickness proximate to fins 103 and a second thickness distal to fins 103 and the first thickness is greater than the second thickness. In some examples, fins 103 can comprise base portions 1031 and upper portions 1032 and base portions 1031 can be wider than upper portions 1032 in cross-sectional view. In the present example, gate region portion 110B is on gate region portion 110A and can surround and cover portions of base portions 1031 and upper portions 1032 of fins 103.

In some examples, semiconductor substrate 101, buffer layer 1015, drift region 102, gate region portion 110A, fins 103, gate region portion 110B, and doped contact regions 104 can comprise or be referred to as a body of semiconductor material 111. In some examples, gate region portion 110B can define a top side or upper side 118 of body of semiconductor material 111 and semiconductor substrate 101 can define a bottom side or lower side 119 of body of semiconductor material 111. Body of semiconductor material 111 can comprise or be referred to as a semiconductor work piece or a semiconductor body.

Vertical, fin-based JFET device 100 further includes a gate contact structure 112 coupled to gate region 110. In one embodiment, gate contact structure 112 may include a nickel (Ni) layer disposed on gate region 110, a first gold (Au) layer disposed on the nickel (Ni) layer, a barrier layer, including, for example, a metal layer (e.g., molybdenum (Mo), titanium (Ti), tantalum (Ta), or similar materials) disposed on the first gold (Au) layer, and a second gold (Au) layer disposed on the barrier layer. In the present example, a drain metal layer 117 is provided at the bottom side of semiconductor substrate 101 (i.e., lower side 119 of body of semiconductor material 111) to form a drain contact. Gate contact structure 112 is an example of a control electrode and drain metal layer 117 is an example of a currently carrying electrode (e.g., a second current carrying electrode). Although not shown, it is understood that vertical, fin-based JFET device 100 can further include various dielectric structures and conductive interconnect structures to isolate and provide electrical contact to the various elements of the device.

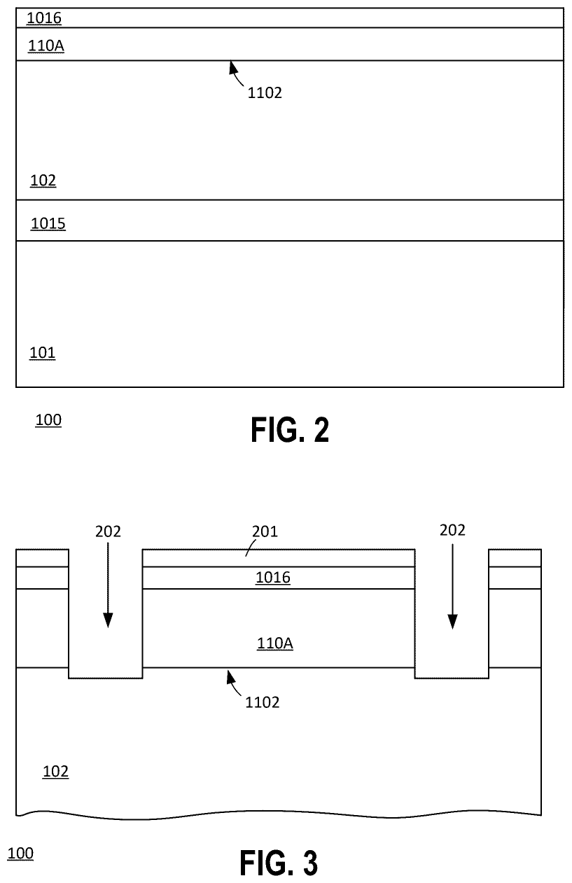

FIGS. 2, 3, 4, 5, and 6 are partial cross-sectional views illustrating an example method of fabricating a vertical, fin-based FET device according to an embodiment of the present description, which can be used to manufacture vertical, fin-based JFET device 100.

With reference to FIG. 2, semiconductor substrate 101 can be provided. In some examples, semiconductor substrate 101 can include an N-type (e.g., N+ doped) III-nitride substrate (e.g., GaN). In an embodiment, semiconductor substrate 101 is an N+ doped III-nitride substrate that is heavily doped with N-type dopants, such as Si or Ge, with a dopant concentration in a range of about 5×10¹⁷ atoms/cm³ to about 5×10¹⁹ atoms/cm³ and a resistivity of less than 0.020 ohm-cm. In some examples, the resistivity of the N+ doped III-nitride substrate may be from about 0.001 ohm-cm to 0.018 ohm-cm, preferably less than 0.016 ohm-cm, and more preferably, less than 0.012 ohm-cm. In other examples, semiconductor substrate 101 can be an engineered substrate, which can include composite, layered, modified, bonded, or heteroepitaxial substrates. This includes engineered GaN substrates, such as GaN-on-SOI, GaN-on-silicon, GaN-on-polysilicon AlN ceramic core, or other substrates designed to reduce dislocations caused by lattice/thermal mismatch (i.e., engineered CTE matching to reduce stress).

Next, semiconductor substrate 101 can be prepared and placed within an epitaxial reactor for a first epitaxial growth process. In some examples, a metal-organic chemical vapor deposition (MOCVD) process can be used for the first semiconductor epitaxial growth process. Alternatively, hydride vapor phase epitaxy (HVPE) or other processes known to one of ordinary skill in the art can be used for the first epitaxial growth process. As used herein, the first epitaxial growth process refers to a series of fabrication steps that are implemented within the same epitaxial reactor without breaking vacuum or exposing semiconductor substrate 101 to the ambient environment. The fabrication steps for the first epitaxial growth process include, but are not limited to, cleaning and semiconductor growth processes.

In the present example, the first epitaxial growth process includes forming buffer layer 1015 on semiconductor substrate 101. In some examples, buffer layer 1015 comprises an N-type conductivity III-nitride layer (e.g., a GaN layer doped with Si or Ge) having a dopant concentration of approximately 1.0×10¹⁸ atoms/cm³ and a thickness of about 0.5 microns. In some examples, buffer layer 1015 functions as a transitional layer between heavily doped semiconductor substrate 101 and drift region 102.

The first epitaxial growth process also includes forming drift region 102 on buffer layer 1015. In the present example, drift region 102 comprises an N-type conductivity III-nitride layer (e.g., a GaN layer doped with Si or Ge) having a first dopant concentration and a thickness dependent upon the desired breakdown voltage of the JFET device. In one embodiment, the first dopant concentration is approximately uniform across the thickness of drift region 102. That is, the first dopant concentration is not intentionally graded across its thickness, but some variation may occur due to effects, such as auto doping. In some examples, drift region 102 can have a dopant concentration (i.e., a first dopant concentration) in a range from about 8.0×10¹⁵ atoms/cm³ to about 5.0×10¹⁶ atoms/cm³ and thickness of about 3 to 10 microns for a device 100 with a rating of 700V. For a device 100 rated at 1200V, the drift region 102 can have a dopant concentration (i.e. a first dopant concentration) in a range from about 8.0×10¹⁵ atoms/cm³ to about 5.0×10¹⁶ atoms/cm⁻³ and thickness of about 5 to 12 microns. Drift region 102 can comprise or be referred to as a uniformly doped as-grown region. In some examples, drift region 102 can be epitaxially grown on buffer layer 1015 at a temperature between 950 and 1200 degrees Celsius. In the present example, drift region 102 does not include or is provided devoid of an intentionally graded N-type conductivity layer at the top side of drift region 102.

The first epitaxial growth process also includes forming gate region portion 110A directly on drift region 102. Gate region portion 110A comprises a P-type conductivity III-nitride layer (e.g., a GaN layer) doped with Mg with a second dopant concentration in a range from about 5.0×10¹⁶ atoms/cm³ to about 5.0×10¹⁸ atoms/cm³, and a thickness in range from 0.3 microns to 0.6 microns. In accordance with the present description, the first dopant concentration of drift region 102 and the second dopant concentration of gate region portion 110A can be tailored in accordance with desired device specification to modulate the electric field in vertical, fin-based JFET device 100 and to set the breakdown voltage. More particularly, in vertical, fin-based JFET device 100, the PN junction formed between drift region 102 and gate region portion 110A functions as a high voltage gate-drain interface. In accordance with the present description, the gate-drain interface (i.e., interface 1102) is characterized as an “as-grown” gate-drain interface. The as-grown gate-drain interface can be characterized as the physical location of the transition point from the N-type conductivity dopant in drift region 102 to P-type conductivity dopant in gate region portion 110A.

As will be described in more detail later, in the present example gate region portion 110A can comprise a dopant concentration that is less than the dopant concentration of gate region portion 110B. In some examples, this configuration provides for a reduced peak electric field and better edge termination performance.

In some examples, the first epitaxial growth process further includes providing a cap layer 1016 on gate region portion 110A. In some examples, cap layer 1016 comprises an undoped III-nitride layer (e.g., a GaN) layer and has a thickness in a range from about 0.2 microns to about 0.6 microns. In some examples, cap layer 1016 can function to accommodate any auto doping from dopant within gate region portion 110A during subsequent processing or to protect gate region portion 110A during the subsequent process steps. Cap layer 1016 may comprise or be referred to as a sacrificial cap layer. After cap layer 1016 is formed, semiconductor substrate 101 can then be removed from the epitaxial reactor. In the present example, this completes the first epitaxial growth process. In some embodiments, cap layer 1016 is formed using a separate epitaxial regrowth process after growth of gate region portion 110A and removal of semiconductor substrate 101 from the epitaxial reactor, using a second insertion of semiconductor substrate 101 into an epitaxial growth reactor.

FIG. 3 illustrates a partial cross-sectional view of vertical, fin-based JFET device 100 after further processing. It is noted that in FIGS. 3-6, semiconductor substrate 101 and buffer layer 1015 are not shown to simplify the description.

In the present example, a mask 201 can be provided over cap layer 1016 and patterned to provide an array of openings comprising rows and columns that correspond to the location for fins 103. In some examples, mask 201 can comprise a hard mask layer of silicon nitride or other materials as known to one of ordinary skill in the art. In some examples, mask 201 is formed using photoresist. After mask 201 is provided and patterned to provide the openings, an etch process can be used to form trenches 202 extending downward through cap layer 1016 and gate region portion 110A. In some examples, trenches 202 extend downward partially into and within drift region 102. That is, the lower ends of trenches 202 are at a location below gate region portion 110A (e.g., below interface 1102). In the present example, trenches 202 define the positions or locations for fins 103. Trenches 202 are an example of first trenches.

In some examples, the etch process to form trenches 202 may include Cl-based chemistry using a reactive ion etch (RIE) process. In some examples, after trenches 202 are formed a cleaning process is carried using a tetramethylammonium hydroxide (TMAH) solution of about 25% by weight, at a temperature of about 85 degrees Celsius, and for a duration of about 30 minutes. In another embodiment, prior to performing a cleaning using the TMAH solution, a pre-cleaning such as piranha clean using a H₂SO₄:H₂O in a volume ratio 2:1 for 2 minutes may also be performed. In some examples, the widths of trenches 202 can be about 0.3 to about 0.6 microns. In the present example, the widths of trenches 202 set the widths for base portions 1031 of fins 103. In some examples, the widths of trenches 202 can be the same. In other examples, the widths can vary in accordance with specific design, device integration, or edge termination requirements.

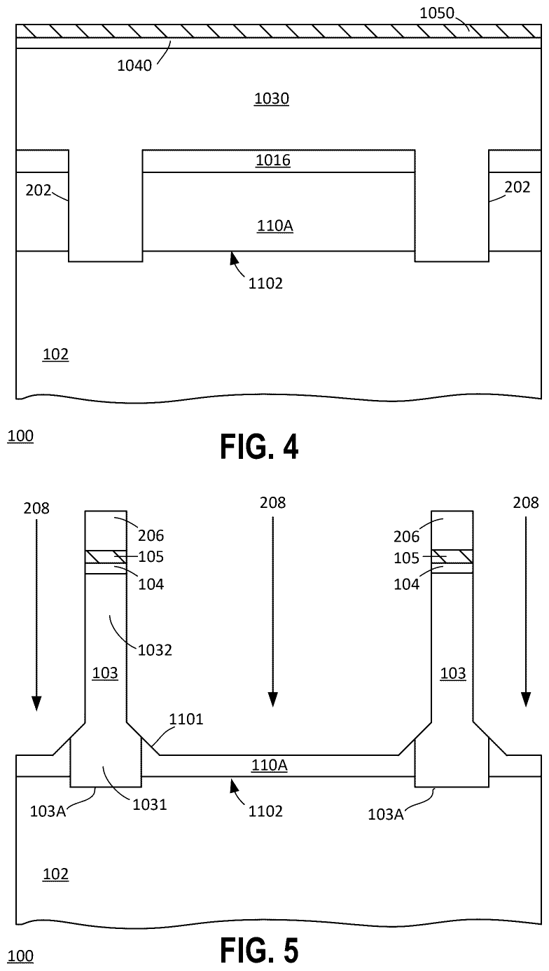

FIG. 4 illustrates a partial cross-sectional view of vertical, fin-based JFET device 100 after further processing. In the present example, mask 201 can be removed and a second epitaxial growth process is used to form N-type III-nitride fin channel region (e.g., GaN doped with Si or Ge) within trenches 202 and over gate region portion 110A. The second epitaxial growth process provides fin channel region 1030 within and filling trenches 202 and extending upward above gate region portion 110A. In some examples, fin channel region 1030 has a thickness between about 0.5 microns and about 0.9 microns as measured from the bottom of trenches 202. In some examples, fin channel region 1030 has a dopant concentration (i.e., a third dopant concentration) of about 1.3×10¹⁷ atoms/cm³. In some examples, fin channel region 1030 has a generally uniform or non-graded dopant profile.

In the present example, the upper surface of fin channel region 1030 can be substantially planar. In some examples, the second epitaxial growth process can be used to form enhancement layer 1040 on the upper surface of fin channel region 1030, which can be a heavily doped N-type conductivity III-nitride layer (e.g., GaN doped with Si or Ge) and can have a dopant concentration of greater than 1.0×10¹⁹ atoms/cm³. In other examples, enhancement layer 1040 can be provided within fin channel region 1030 using ion implantation or other doping techniques as known to one of ordinary skill in the art. In some examples, contact layer 1050 can then be provided on enhancement layer 1040, which can comprise a titanium-nitride (TiN) layer. In an embodiment, contact layer 1050 can be omitted. In the present example, contact layer 1050 can be used to provide contacts 105 (e.g., source contacts) for vertical, fin-based JFET device 100.

FIG. 5 illustrates a partial cross-sectional view of vertical, fin-based JFET device 100 after further processing. In the present example, a patterned hard mask 206 is provided on contact layer 1050. In some examples, patterned hard mask 206 can comprise silicon nitride (Si₃N₄) and can be formed with a thickness of about 400 nm by PECVD at about 300° C. In some examples, openings in patterned hard mask 206 can be formed using RIE with F-based chemistry. In the present example, patterned hard mask 206 can be aligned with trenches 202 and is configured to provide fins 103 in an array of rows and columns.

After patterned hard mask 206 is provided, an etch process is performed using patterned hard mask 206 as a mask to form recess region 208 and further forming a plurality of fins 103, doped contact regions 104, and contacts 105. In the present example, recess region 208 is etched into fin channel region 1030 formed from the second epitaxial growth process and further etched into gate region portion 110A formed from the first epitaxial growth process. Recess region 208 exposes gate region portion 110A as shown in FIG. 5. In this example, recess region 208 is positioned so that it aligns directly with trenches 202.

In some examples, fins 103 each have a minimum width of about 0.2 microns and a height in a range between about 0.7 microns and 0.8 microns and are spaced apart from each other by a space of about 2 microns, i.e., the fin pitch is about 2.2 μm. To achieve uniform height of the fins, good controllability of the depth of the etch process is utilized. The etch process to form recess region 208 can include Cl-based chemistry using an RIE process. Recess region 208 can comprise or also be referred to as a second trench or second trenches. In an embodiment, the etch process may stop when about 0.2 microns of gate region portion 110A is removed. In the present example, recess region 208 does not extend through gate region portion 110A to drift region 102 (i.e., gate region portion 110A is laterally interposed between drift region 102 and recess region 208), which preserves as-grown interface 1102. In one embodiment, after forming recess region 208, the TMAH cleaning process described previously with trenches 202 can be used including using a piranha pre-clean.

As shown in FIG. 5, gate region portion 110A surrounds and adjoins at least a portion of base portions 1031 of fins 103. That is, fins 103 extend upward from openings in gate region portion 110A. In the present example, recess region 208 can provide gate region portion 110A with a non-uniform thickness. More particularly, the thickness of gate region portion 110A can increase proximately to fins 103 providing gate region portion 110A with a tapered upper surface 1101.

As further shown in FIG. 5, the width of fins 103 can be non-uniform and base portions 1031 of fins 103 can be wider than upper portions 1032. In accordance with the present description, with base portions 1031 being wider and more heavily doped at the lower interface with drift region 102, the issues associated with the parasitic high threshold voltage transistor described with FIG. 14 (with the bottom portions of fins 403 adjoining the more lightly doped graded doped layer 402A) are reduced and on-resistance is improved.

It is understood that base portions 1031 can have a shape different from the shape shown in FIG. 5 after the etch process. Embodiments are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. In the drawings, the bottom portions of the fins are shown as having a 90 degrees angle with the surface of gate region portion 110A. However, it is understood that the bottom portion of the fins may have rounded or curved features. Thus, the regions illustrated in the figures are schematic in nature and their shapes are not intended to illustrate the actual shape of a region of a device and are not intended to limit the scope of the invention.

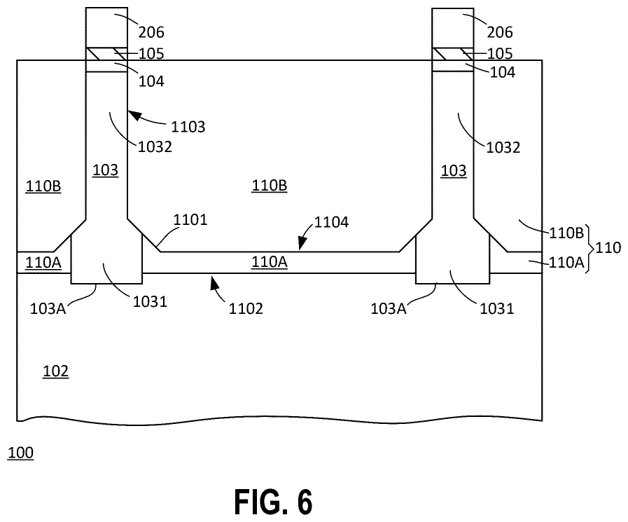

FIG. 6 illustrates a partial cross-sectional view of vertical, fin-based JFET device 100 after further processing. In the present example, a third epitaxial growth process is used to form gate region portion 110B within recess region 208, adjoining fins 103, and on gate region portion 110A. In the present example, gate region portion 110B comprises a P-type III-nitride layer (e.g., a GaN layer doped with Mg) that is grown within recess region 208 at a temperature of about 950 degrees Celsius up to a thickness that is substantially planar to the bottom of contacts 105. In some examples, the thickness of gate region portion 110B is about 1,000 nm. Accordingly, in some examples, the regrowth is substantially planar with the bottom of the patterned hard mask 206 or contacts 105, that is, above doped contact regions 104. The thickness of gate region portion 110B can take into account the thickness of fins 103, the etch into gate region portion 110A, and the thickness of enhancement layer 1040.

Gate region portion 110B can have dopant concentration (i.e., a fourth dopant concentration) of about 2×10¹⁹ atoms/cm³. Thereafter, a thermal anneal (e.g., a rapid thermal annealing in N₂ at 850 degrees Celsius for 5 minutes) is performed to activate the Mg dopant atoms with gate region portion 110B and gate region portion 110A. The Mg atoms can be activated in the P-type GaN layer in an amount of greater than 10% by weight. In other examples, the Mg dopant in gate region portion 110A can be activated with a similar thermal anneal after the first epitaxial growth process. In the present example, doped contact regions 104 are formed from the heavily doped N-type enhancement layer 1040 present between fins 103 and contacts 105 to improve contact resistance between fins 103 and contacts 105.

In accordance with the present description, the third epitaxial growth process provides gate region portion 110B as a regrown region. More particularly, gate region portion 110B comprises a regrown interface 1103 between gate region portion 110B and fins 103. Regrown interface 1103 defines gate-source PN junctions that control the channel regions of vertical, fin-based JFET device 100. In the present example, the gate-source PN junctions are formed as regrown interfaces as opposed to as-grown interface 1102 between gate region portion 110A and drift region 102. Further, gate region portion 110B forms a regrown interface 1104 with gate region portion 110A, which is above as-grown interface 1102. In present example, separate gate region portions 110A and 110B provide beneficial independent adjustment and optimization of the gate-source (channel) PN junction and gate-drift region PN junction formation.

In accordance with the present description, the dopant concentration of gate layer portion 110A (i.e., the second dopant concentration) is about 25% or less than the dopant concentration of gate layer portion 110B (i.e., the fourth dopant concentration). In some examples, the second dopant concentration can be in a range from about 0.25% to about 25% of the fourth dopant concentration.

In subsequent manufacturing steps, patterned hard mask 206 can be removed and further processing can be done to complete vertical, fin-based JFET device 100. This can include, for example, providing passivation layers, conductive vias, gate contact structure 112, additional conductive interconnect layers, wafer thinning, and drain metal layer 117.

In an example, vertical, fin-based JFET device 100 can be configured as an N-channel enhancement mode device, which can be operated as follows. In the OFF state, the gate-to-source voltage (V_{GS}) is typically at 0 volts or a slightly negative voltage of −2 volts to −5 volts. Also, the drain-to-source voltage (V_{DS}) is greater than zero (i.e., the drain metal layer 117 being positive with respect to the source electrode (e.g., contacts 105), which is usually 0 volts or grounded). Under these conditions, the gate-to-channel junction is reverse biased, the channels within fins 103 are depleted, and current does not flow from the drain region (i.e., semiconductor substrate 101 and drift region 102) through the channels (i.e., fins 103) to the source electrode (i.e., contacts 105). That is, when the gate-to-channel junction is under reverse bias, the leakage current remains low. Also, in the OFF state, the gate-to-drain junction can become deeply reverse biased, and this junction supports a primary part of the high electric field. More particularly, the peak electric field is located proximate to the gate-to-drain junction. In accordance with the present description, by using an as-grown gate region portion 110A in combination with a regrown gate region portion 110B, the device architecture relocates the regrown interface away from the area where the peak electric field occurs. The primary high field PN junction is instead established between drift region 102 and the as-grown gate region portion 110A, ensuring that this critical junction is formed without exposure to regrowth-related contamination or defect generation. As a result, the gate-to-drain junction exhibits significantly reduced defect density compared to prior designs relying on regrown interfaces. This enhances device robustness, breakdown reliability, and long-term operating lifetime.

To switch vertical, fin-based JFET device 100 to the ON state, a positive gate-to-source voltage is applied (e.g., 2 volts to 5 volts) to forward bias the gate-to-channel junction and form a low-resistance channel to allow current to flow from the drain electrode, through fins 103, to the source electrode. Typically, the forward bias on the gate-to-channel junction is sufficient to modulate the depletion layer but is not normally driven into heavy conduction. In addition, a positive voltage can remain on the drain electrode, and the source electrode can remain at 0 volts or grounded.

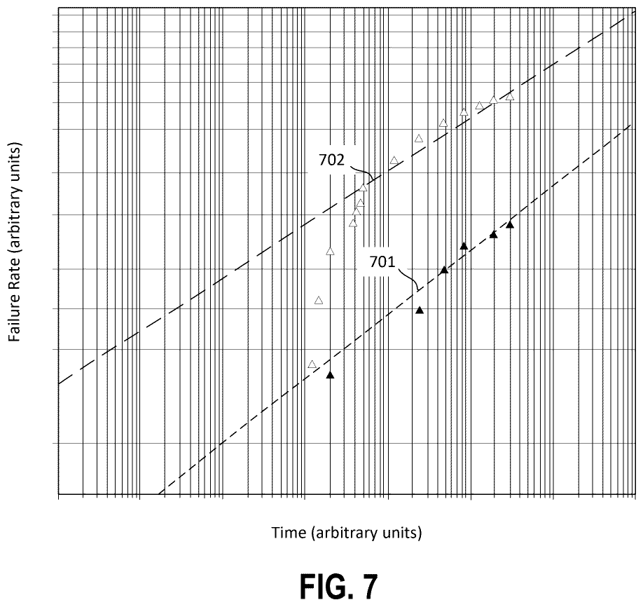

FIG. 7 is a Weibull Cumulative Distribution Function (Weibull CDF) chart that shows the probability of time to failure for an as-grown PN junction according to the present description (e.g., the PN junction formed by gate region portion 110A and drift region 102 in vertical, fin-based JFET device 100) compared to a regrown PN junction (e.g. the regrown PN junction between gate region 410 and graded doped layer 402A in vertical, fin-based JFET device 400 of FIG. 14) under high temperature, reverse-biased (HTRB) conditions. Data line 701 with the filled triangles represents data for the as-grown PN junction, and data line 702 with the unfilled triangles represents data for the regrown PN junction. As shown in FIG. 7, the as-grown gate-to-drain PN junction provides a 10× improvement in HTRB lifetime performance compared to the regrown PN junction. More particularly, the as-grown configuration of the gate-to-drain PN junction formed by gate region portion 110A and drift region 102 enables the formation of a lower defect junction, which improves the lifetime performance of vertical, fin-based JFET device 100.

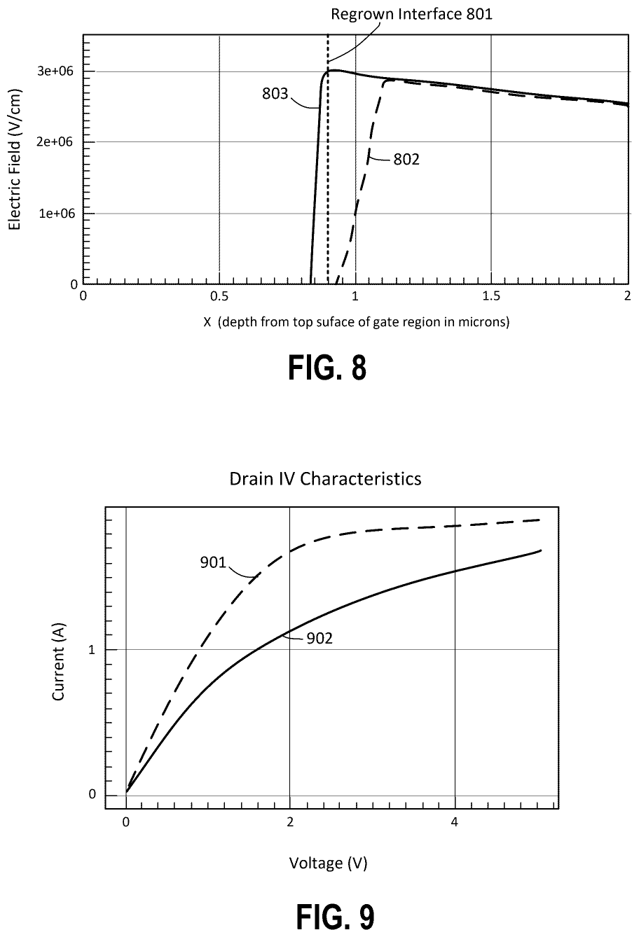

FIG. 8 is a graph illustrating the shift in the location of the high electric field for a vertical, fin-based JFET device according to the present description compared to a prior vertical, fin-based JFET device. The electric field measurements in FIG. 8 were taken along reference cut-line CL shown in FIG. 1 for vertical, fin-based JFET device 100 and reference cut-line CL shown in FIG. 14 for vertical, fin-based JFET device 400. In the present example, CL is located at a distance Y (i.e., the horizontal direction) of about 1 micron from the center of the left fin 103 in FIG. 1 and from the center of the left fin 403 in FIG. 14. The vertical dashed line 801 in FIG. 8 represents the location of the regrown interface in the X direction or depth (90 degrees to the cut-line CL) from the top surface of the gate region. More particularly, the X direction is perpendicular to or in a vertical direction with respect to the top surface of the gate regions 110 and 410. In the present example, the regrown interface (dashed line 801) corresponds to the interface between gate region portion 110B and gate region portion 110A in vertical, fin-based JFET device 100 and the interface between gate region 410 and drift region 402/402A in vertical, fin-based JFET device 400.

Data line 802 is electric field data for vertical, fin-based JFET device 100 in operation, and data line 803 is electric field data for vertical, fin-based JFET device 400 in operation. As is evident in FIG. 8, the electric field in vertical, fin-based JFET device 100 is approximately 97% lower in the vicinity of the regrown interface compared to that in vertical, fin-based JFET device 400. In accordance with the present description, by moving the regrown interface away from the peak electric field location, the reliability of vertical, fin-based JFET device 100 is improved compared to that of vertical, fin-based JFET device 400.

FIG. 9 is a graph illustrating drain current/voltage (I/V) characteristics for a vertical, fin-based JFET device according to the present description compared to a prior vertical, fin-based JFET device. In FIG. 9, data line 901 is I/V data for vertical, fin-based JFET device 100 and data line 902 is I/V data for vertical, fin-based JFET device 400. As described previously, one feature of vertical, fin-based JFET device 100 is that base portions 1031 of fins 103 have a heavier doping concentration where base portions 1031 interface with or couple to drift region 102. In contrast, in vertical, fin-based JFET device 400, the base regions of fins 403 have a lower doping concentration because of the graded doped layer 402A. More particularly, in vertical, fin-based JFET device 100, base portions 1031 have a uniform doping that matches the overall doping of fins 103 and avoids the graded doping feature of the prior device. Among other things, this feature of vertical, fin-based JFET device 100 improves the saturated drain current (I_{DSAT}) as shown in FIG. 9.

It was further determined using Deep Level Transient Spectroscopy (DLTS) that the as-grown gate-to-drain PN junction of the present description has improved junction quality compared to a regrown gate-to-drain PN junction. For example, the DLTS data showed that the as-grown PN junction had three (3) electron trap levels compared to 11 for the regrown PN junction. Also, the as-grown PN junction had a cumulative electronic trap density of 2.5×10¹⁴ cm⁻³ compared to 6.1×10¹⁵ cm⁻³ for the regrown PN junction. In addition, the as-grown PN junction had a cumulative electron trap density capture cross-section of three (3) cm⁻¹ compared to 1182 cm⁻¹ for the regrown PN junction. Additionally, the as-grown PN junction had three (3) hole trap levels compared to six (6) for the regrown PN junction. Further, the as-grown PN junction had a cumulative hole trap density of 1.1×10¹⁶ cm⁻³ compared to 1.6×10¹⁶ cm⁻³ for the regrown PN junction. Finally, the as-grown PN junction had a cumulative hole trap density capture XS of 11 cm⁻¹ compared to 105 cm⁻¹ for the regrown PN junction. This data quantifies the benefits of the as-grown PN junction as implemented herein by providing a lower-defect as-grown gate-to-drain junction (i.e., the as-grown PN junction provided by drift region 102 and gate region portion 110A).

Typically, fins used in vertical, fin-based JFET devices are provided in large arrays comprising patterns or arrays of columns and rows of fins across a semiconductor substrate. It is understood that the uniformity of both the lithography process and the etch processes used to fabricate vertical, fin-based JFET devices can vary significantly between a region with a regular pattern of fins and a region with a sparse pattern of fins. Such a variation can occur at the edges of the array of fins. For example, the presence of a large sparse area next to a regular array can lead to differences in exposure dose due to proximity effects, which can cause the resist linewidth to vary between the center of the array and the edges of the array, with a resulting increase in the electrical variation of the fin devices near the edge of the array. Additionally, the presence of a large sparse pattern area next to a regular pattern array can lead to differences in etch rate caused by variation in the amount of etchant consumed in the sparse pattern region versus the amount consumed in the regular pattern array. Such differences in etch rate can affect both fin width and fin height, with a resulting increase in the electrical variation of the fin devices near the edge of the array.

In addition, it is understood that local pattern density in the fin array can affect the uniformity of the regrown-gate region process. Such variations in the growth rate can lead to non-uniform height of growth on the fin sidewalls, which will affect the effective channel length of the JFET device, and can cause variation in leakage current at high voltage and in threshold voltage, for fins near the edges of the array. Variation in the growth rate may also affect the uniformity of dopant incorporation in the GaN during regrowth, which in turn can cause variation in threshold voltage.

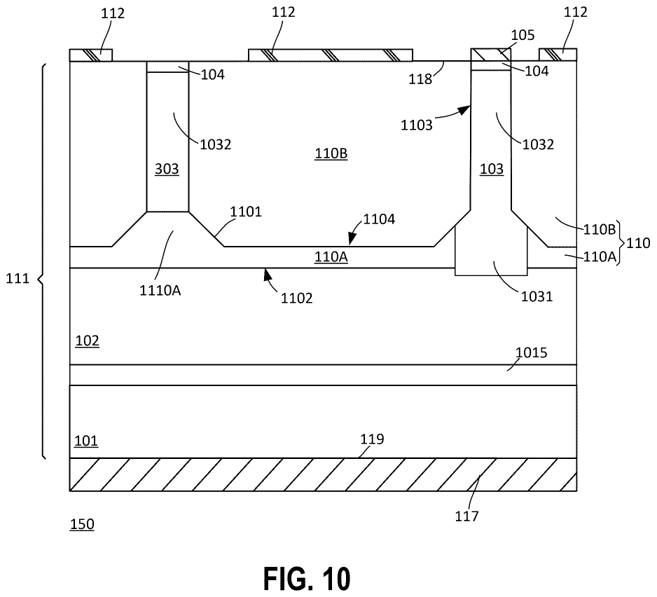

FIG. 10 is a partial cross-sectional view illustrating a vertical, fin-based JFET device 150 that includes fin 103 and an inactive fin 303 according to an embodiment of the present description. In the present example, fin 103 can comprise, or be referred to as an active fin. Vertical, fin-based JFET device 150 has some similarities in construction to vertical, fin-based JFET device 100 and such similarities will not be repeated here. In this regard, only certain distinctions will be discussed hereinafter.

In the present example, vertical, fin-based JFET device 150 comprises inactive fin 303, which can be part of a plurality of inactive fins 303 placed in specific locations within vertical, fin-based JFET device 150. More particularly, inactive fin 303 can be provided as part of an array or arrays of inactive fins 303 that are placed in areas of semiconductor substrate 101 to address, among other things, the uniformity issues associated with lithography processes, etch processes, and gate-regrowth processes described previously. Such areas can include, but are not limited to, edge regions of semiconductor substrate 101 where edge-termination structures are provided.

In accordance with the present description, inactive fin 303 comprises upper portion 1032 similar to fin 103 but does not include a base portion 1031. Instead, inactive fin 303 adjoins part 1110A of gate region portion 110A. With inactive fin 303 comprising an N-type conductivity and gate region portion 110A (which includes part 1110A) comprising a P-type conductivity, inactive fin 303 is electrically isolated from drift region 102 and does not provide a channel for current conduction during the operation of vertical, fin-based JFET device 150. That is, gate region portion 110A is interposed between inactive fin 303 and drift region 102 so that gate region portion 110A electrically isolates inactive fin 303 from drift region 102. In some examples, contact 105 does not contact inactive fin 303, and inactive fin 303 can be characterized as an electrically floating structure.

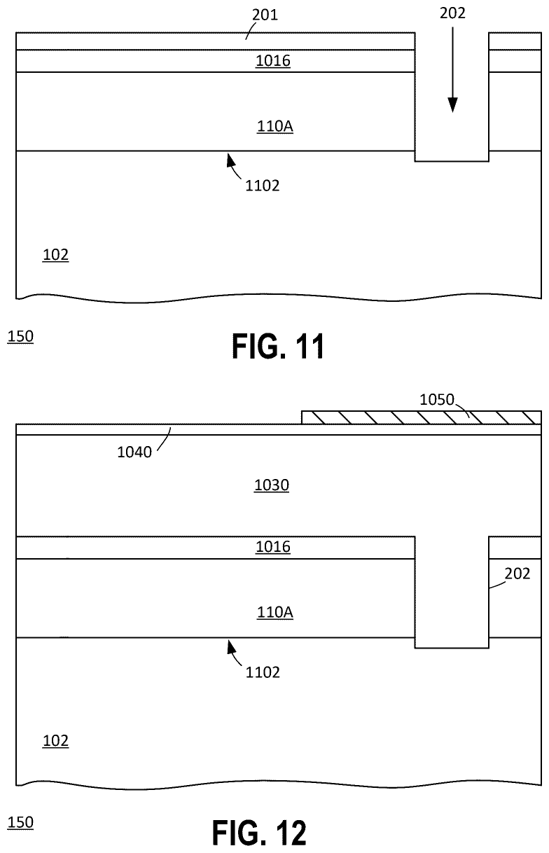

FIGS. 11, 12, and 13 are partial cross-sectional views illustrating an example method of fabricating a vertical, fin-based JFET device according to an embodiment of the present description, which can be used to manufacture vertical, fin-based JFET device 150. The method described with FIGS. 11-13 has some similarities to the method described with FIGS. 3-5, and such similarities will not be repeated here. In this regard, only certain distinctions will be discussed hereinafter.

In the present example, semiconductor substrate 101 and the associated layers described in FIG. 2 can be provided. FIG. 11 illustrates a partial cross-sectional view of vertical, fin-based JFET device 150 after further processing. It is noted that in FIGS. 11-13, semiconductor substrate 101 and buffer layer 1015 are not shown. In the present example, mask 201 can be provided over cap layer 1016 and patterned to provide openings corresponding to the location for fins 103, but in contrast to the example of FIG. 3, openings in mask 201 are not provided where inactive fins 303 will be formed.

FIG. 12 illustrates a partial cross-sectional view of vertical, fin-based JFET device 150 after further processing. In the present example, mask 201 can be removed, and the second epitaxial growth process is used to form N-type III-nitride fin channel region 1030 (e.g., GaN doped with Si or Ge) within trenches 202 and over gate region portion 110A. The second epitaxial growth process provides fin channel region 1030 within and filling trenches 202 and extending upward above gate region portion 110A. In some examples, the second epitaxial growth process can be used to form enhancement layer 1040 at the upper part of fin channel region 1030. In some examples, contact layer 1050 can then be provided on enhancement layer 1040 as described previously. In some examples, if contact layer 1050 is included, it can be patterned to remove portion(s) that overlie the locations for inactive fins 303 as shown in FIG. 12.

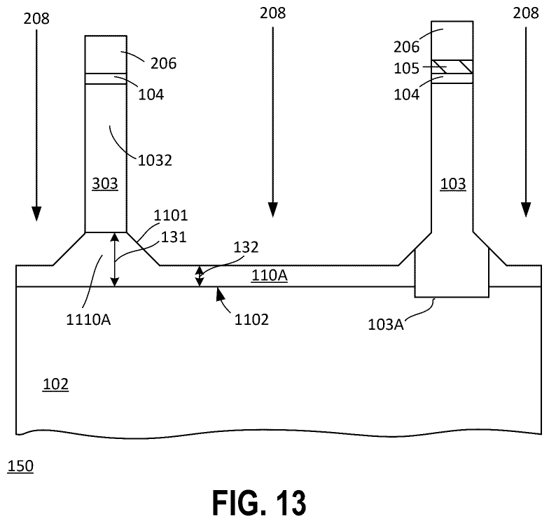

FIG. 13 illustrates a partial cross-sectional view of vertical, fin-based JFET device 150 after further processing. In the present example, patterned hard mask 206 is provided on contact layer 1050 as described previously. In the present example, patterned hard mask 206 can be aligned with trenches 202 and configured to provide fins 103 in an array of rows and columns. In addition, patterned hard mask 206 can be aligned using alignment keys or other alignment structures to provide inactive fins 303 in an array of rows and columns.

After patterned hard mask 206 is provided, an etch process is performed using patterned hard mask 206 as a mask to form fins 103 with doped contact regions 104 and contacts 105, e.g., patterned metal contacts, and inactive fins 303 with doped contact regions 104. It is understood that contacts 105 can be included with inactive fins 303, but such contacts 105 are not subsequently electrically connected to the source metal contact. In accordance with the present description, inactive fins 303 are provided on part 1110A of gate region portion 110A and are electrically isolated from drift region 102. In some examples, part 1110A is thicker than those parts of gate region portion 110A that form an interface with gate region portion 110B. That is, part 1110A has a first thickness 131 and the part of gate region portion 110A that forms a generally horizontal interface in cross-section view with gate region portion 110B has a second thickness 132 that is less than the first thickness. This feature provides beneficial electrical isolation of inactive fins 303 from drift region 102. Vertical, fin-based JFET device 150 can then be processed as described previously with FIG. 6 to provide the example shown in FIG. 10.

In summary, inactive fin 303 can be used in selected areas of vertical, fin-based JFET device 150 to address, among other things, the uniformity issues associated with lithography processes, etch processes, and gate regrowth processes described previously. Such areas can include, but are not limited to, edge regions of semiconductor substrate 101 where edge termination structures are provided.

From all of the foregoing, those skilled in the art can determine that in an example, a semiconductor device includes a vertical fin-based FET including a gate region, a portion of the gate region making contact to a drain region fabricated within a single epitaxial growth process, wherein the single epitaxial growth process includes modifying a peak electric field at a junction of the gate region and the drain region during operation to thereby improve lifetime performance or increase breakdown voltage. In another example, the semiconductor device can further include independent p-side control of gate-source and gate-drift junctions to thereby select breakdown voltage, channel control, drain current, and edge termination features of the semiconductor device.

In a further example, any crystalline damage occurring during fabrication of the FET occurs at interfaces that experience relatively low voltages/fields during device operation. In a still further example, the semiconductor device can further include one or more non-active fins to thereby improve structural uniformity across the semiconductor device including the edge termination features. In another example, the gate region can be separated into a first portion and a second portion to thereby facilitate fabrication of the one or more nonactive fins, at least one of the one or more non-active fins comprising an N-type fin that is not electrically connected to an N-type drain of the semiconductor device.

From all of the foregoing, those skilled in the art can determine that in an example, a semiconductor device includes a vertical fin-based FET with fin channel semiconductor regions formed from a second semiconductor epitaxial growth applied to a patterned first semiconductor epitaxial growth including a drift region.

From all of the foregoing, those skilled in the art can determine that in an example, a semiconductor device, includes a vertical fin-based FET with a gate semiconductor region partially formed from a third, selective-area semiconductor epitaxial growth applied to a combination of a patterned second semiconductor epitaxial growth including fin channel regions and a patterned first epitaxial growth including the gate semiconductor region. In another example, the semiconductor device can further comprise one or more non-active fins to thereby improve structural uniformity across the semiconductor device including an edge termination region.

In a further example, the one or more non-active fins improve topographical uniformity of the third, selective-area epitaxial growth process and facilitate controlling a layer thickness in a portion of the semiconductor device where the edge termination region is fabricated.

In summary, structures and methods have been described for semiconductor devices including vertical, fin-based FET devices having an improved gate-drain interface. More particularly, a first portion of the gate region, specifically the part that contacts the drain, is formed during the same epitaxial growth process used to create the drift region portion of the drain region, rather than through a separate, second epitaxial growth step. In the present example, a second portion of the gate region is formed on the first portion at a later step in fabrication. The fabrication method enhances the structural and electrical integrity of the gate-drain interface by forming the drain-contacting portion of the gate region during the same epitaxial growth step used to form the drift region portion of the drain region. Among other things, consolidating these regions into a single epitaxial process reduces heterointerfaces associated with regrown junctions and reduces defect densities, such as threading dislocations, point defects, and impurity incorporation, that commonly arise during separate regrowth steps. As a result, the gate-drain junction benefits from a more uniform doping profile, improved crystallographic alignment, and reduced trap-assisted leakage pathways, enabling higher breakdown voltages. The methods and structures described herein can also facilitate increased drain current and a more robust edge termination region compared to prior designs.

While various embodiments of the invention have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations, but can be implemented using a variety of alternative architectures and configurations. Additionally, although the disclosure is described above in terms of various exemplary embodiments and implementations, it should be understood that the various features and functionality described in one or more of the individual embodiments are not limited in their applicability to the particular embodiment with which they are described. They instead can be applied alone or in some combination, to one or more of the other embodiments of the disclosure, whether or not such embodiments are described, and whether or not such features are presented as being a part of a described embodiment. Thus, the breadth and scope of the present disclosure should not be limited by any of the above-described exemplary embodiments.

It will be appreciated that, for clarity purposes, the above description has described embodiments of the invention with reference to different functional units and processors. However, it will be apparent that any suitable distribution of functionality between different functional units, processors or domains may be used without detracting from the invention. For example, functionality illustrated to be performed by separate processors or controllers may be performed by the same processor or controller. Hence, references to specific functional units are only to be seen as references to suitable means for providing the described functionality, rather than indicative of a strict logical or physical structure or organization.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A vertical, fin-based FET device, comprising:
a semiconductor substrate characterized by a first conductivity type;
a drift region over the semiconductor substrate and characterized by the first conductivity type and a first dopant concentration;
a first gate region portion on the drift region and characterized by a second conductivity type opposite to the first conductivity type and a second dopant concentration;
trenches extending through the first gate region portion to the drift region;
fins within the trenches, extending above the first gate region portion, and characterized by the first conductivity type and a third dopant concentration; and
a second gate region portion on the first gate region portion, surrounding the fins, and characterized by the second conductivity type and a fourth dopant concentration;
wherein:
the first gate region portion and the drift region form an as-grown interface;
the second gate region portion and the first gate region portion form a regrown interface; and
the fins comprise base portions within the trenches and upper portions coupled to the base portions and extending above the trenches.

2. The vertical, fin-based FET device of claim 1, wherein:
the first dopant concentration is a uniform dopant concentration; and
the second dopant concentration is less than the fourth dopant concentration.

3. The vertical, fin-based FET device of claim 1, wherein:
the base portions are wider than the upper portions of the fins; and
the semiconductor substrate comprises an engineered GaN substrate.

4. The vertical, fin-based FET device of claim 1, wherein:
the first gate region portion comprises a first thickness proximate to the fins and a second thickness distal to the fins; and
the first thickness is greater than the second thickness.

5. The vertical, fin-based FET device of claim 1, wherein:
the semiconductor substrate, the drift region, the first gate region portion, the fins, and the second gate region portion comprise III-nitride semiconductor materials.

6. The vertical, fin-based FET device of claim 1, wherein:
the drift region is devoid of a graded dopant layer of the first conductivity type interposed between the drift region and the first gate region portion.

7. The vertical, fin-based FET device of claim 1, further comprising:
an inactive fin on the first gate region portion, wherein the first gate region portion electrically isolates the inactive fin from the drift region.

8. The vertical, fin-based FET device of claim 7, wherein:
the inactive fin is an electrically floating structure.

9. The vertical, fin-based FET device of claim 1, wherein:
the base portions of the fins comprise first ends that coupled to the drift region;
the first ends lie within a first plane; and
the as-grown interface lies within a second plane that is different than the first plane.

10. The vertical, fin-based FET device of claim 1, wherein:
the first gate region portion comprises a tapered upper surface at a location that is adjacent to the fins.

11. A vertical, fin-based FET device, comprising:
a semiconductor substrate characterized by a first conductivity type;
a drift region over the semiconductor substrate and characterized by the first conductivity type;
a first gate region portion on the drift region and characterized by a second conductivity type opposite to the first conductivity type;
a second gate region portion on the first gate region portion and characterized by the second conductivity type; and
fins characterized by the first conductivity type, coupled to the drift region, and extending through the first gate region portion and the second gate region portion;
wherein:
the first gate region portion and the drift region form an as-grown PN junction;
the second gate region portion and the first gate region portion form a regrown interface; and
the fins comprise base portions adjacent to the drift region and upper portions coupled to the base portions.

12. The vertical, fin-based FET device of claim 11, wherein:
the drift region comprises a uniform dopant concentration; and
the first gate region portion has a lower dopant concentration than that of the second gate region portion.

13. The vertical, fin-based FET device of claim 11, further comprising:
trenches extending through the first gate region portion, wherein the base portions of the fins are within the trenches.

14. The vertical, fin-based FET device of claim 11, wherein:
the semiconductor substrate, the drift region, the first gate region portion, the fins, and the second gate region portion comprise III-nitride semiconductor materials.

15. The vertical, fin-based FET device of claim 11, further comprising:
an inactive fin on the first gate region portion, wherein the first gate region portion is interposed between the inactive fin and the drift region so that the first gate region portion electrically isolates the inactive fin from the drift region.

16. A method for fabricating a vertical, fin-based FET device comprising:
providing a semiconductor substrate characterized by a first conductivity type;
in a first epitaxial growth process:
forming a drift region over the semiconductor substrate and characterized by the first conductivity type and a first dopant concentration; and
forming a first gate region portion on the drift region and characterized by a second conductivity type opposite to the first conductivity type and a second dopant concentration;
forming trenches extending through the first gate region portion to the drift region;
in a second epitaxial growth process, forming a fin channel region within the trenches, and over the first gate region portion, the fin channel region characterized by the first conductivity type and a third dopant concentration;
forming a recess region in the fin channel region to form fins; and
in a third epitaxial growth process, forming a second gate region portion on the first gate region portion, surrounding the fins, and characterized by the second conductivity type and a fourth dopant concentration;
wherein:
the first epitaxial growth process is an in-situ process that provides the first gate region portion and the drift region as an as-grown interface;
the second gate region portion and the first gate region portion form a regrown interface; and
the fins comprise base portions within the trenches and upper portions coupled to the base portions and extending above the trenches.

17. The method of claim 16, wherein:
forming the drift region comprises providing the first dopant concentration as a uniform dopant concentration; and
forming the recess region comprises:
aligning the recess region to the trenches; and
providing the base portions wider than the upper portions of the fins.

18. The method of claim 16, wherein:
providing the recess region comprises providing the first gate region portion with a first thickness proximate to the fins and a second thickness distal to the fins; and
the first thickness is greater than the second thickness.

19. The method of claim 16, wherein:
forming the fins comprises providing an inactive fin on the first gate region portion; and
the first gate region portion electrically isolates the inactive fin from the drift region.

20. The method of claim 16, wherein:
the semiconductor substrate, the drift region, the first gate region portion, the fins, and the second gate region portion comprise III-nitride semiconductor materials.
